(19) United States
(12) Patent Application Publication
(10) Pub. No.: US 2025/0299986 A1
(43) Pub. Date: Sep. 25, 2025

(54) POSITIONING DEVICE AND POSITIONING METHOD

(71) Applicant: Panasonic Intellectual Property Management Co., Ltd., Osaka (JP)

(72) Inventor: RYO FUJITA, Hyogo (JP)

(21) Appl. No.: 19/227,543

(22) Filed: Jun. 4, 2025

Related U.S. Application Data
(63) Continuation of application No. PCT/JP2023/044921, filed on Dec. 14, 2023.

(30) Foreign Application Priority Data
Dec. 21, 2022 (JP) 2022-204365

(51) Int. Cl. H01L 21/67; G06T 7/00

(52) U.S. Cl. CPC H01L 21/67259; G06T 7/0004; G06T 2207/30148

(57) ABSTRACT

Positioning device (100) includes joining head (2), joining stage (4), optical unit (3) that captures an image of at least one of first component (PI) and second component (P2), and processor (6) that calculates a position correction amount of first component (P1) and second component (P2) based on the image captured by optical unit (3).

### TECHNICAL FIELD

The present disclosure relates to a positioning device and a positioning method used to position, for example, an electronic component.

### BACKGROUND ART

Conventionally, when an electronic component or the like is manufactured, positions of components such as a substrate and chip components are grasped using a camera, and each component is positioned. At this time, movement for correcting the positional deviation of each component is performed on the basis of the amount of misalignment recognized by the camera.

For example, an apparatus in PTL 1 includes a bond head including a component gripper, a first drive system that moves a carrier, a second drive system that moves the bond head back and forth between a nominal work position and a standby position, a driver attached to the bond head in such a way as to rotate the component gripper or a rotational driver that rotates a substrate about an axis, a substrate camera attached to the carrier, and a component camera. The substrate includes a substrate mark. The component camera and the substrate camera detect the substrate mark.

### CITATION LIST

### Patent Literature

PTL 1: Unexamined Japanese Patent Publication No. 2018-190958

### SUMMARY OF THE INVENTION

In PTL 1, in order to handle small workpieces, it is necessary to bring image capture areas of substrate cameras close to each other, and in order to realize this, it is necessary to thin a shaft connecting the driver and the component gripper. For this reason, rigidity might decrease to deteriorate mounting accuracy. In addition, because an optically necessary space is larger on a lens side than at a recognition position between the recognition position and a lens, it might be difficult to configure the shaft connecting the gripper and the head depending on size of a workpiece.

The present disclosure, therefore, aims to provide a positioning device and a positioning method capable of handling small workpieces.

In order to achieve the above object, a positioning device according to an exemplary embodiment of the present disclosure is a positioning device that performs positioning when a first component is mounted on a second component, the positioning device including a joining head that holds the first component, a joining stage on which the second component is placed, an optical unit that captures an image of at least one of the first component and the second component, and a processor that calculates a position correction amount of the first component and the second component based on the image captured by the optical unit, in which a vibration suppressing member for suppressing transmission of vibration from the joining head to the joining head is disposed between the optical unit and the joining head, or the optical unit and the joining head are disposed apart from each other. The optical unit includes a first camera for capturing the image, a lens disposed to correspond to the first camera, and an optical element that changes an optical axis direction of the first camera. The optical element includes a reflection mirror disposed to correspond to the first camera, and a reflection prism having a reflection surface. The joining head includes a first movement mechanism that is separated from the optical unit and that moves the joining head in a first direction that is a direction parallel to a placement surface of the joining stage, and a holding surface that holds the first component on a lower surface. The optical unit includes a second movement mechanism that moves, when the first camera captures the image of at least one of the first component and the second component, the reflection prism in a second direction that is a vertical direction perpendicular to the first direction.

According to the present disclosure, it is possible to handle small workpieces.

### BRIEF DESCRIPTION OF THE DRAWINGS

FIG. 1A is a front view and a side cross-sectional view of a positioning device according to a first exemplary embodiment.

FIG. 1B is a bottom cross-sectional view of the positioning device according to the first exemplary embodiment.

FIG. 2 is a diagram illustrating a method for adjusting focuses in cameras according to the first exemplary embodiment.

FIG. 3 is a side view illustrating condensing ranges of the cameras according to the first exemplary embodiment.

FIG. 4 is a flowchart illustrating operation of the positioning device according to the first exemplary embodiment.

FIG. 5A is a diagram illustrating the operation of the positioning device according to the first exemplary embodiment.

FIG. 5B is another diagram illustrating the operation of the positioning device according to the first exemplary embodiment.

FIG. 6 is a diagram illustrating a positioning device according to a second exemplary embodiment.

FIG. 7 is a flowchart illustrating operation of the positioning device according to the second exemplary embodiment.

FIG. 8 is a front view and a side cross-sectional view of a positioning device according to a third exemplary embodiment.

FIG. 9 is a flowchart illustrating operation of the positioning device according to the third exemplary embodiment.

FIG. 10 is a diagram illustrating an example of images captured by cameras according to the third exemplary embodiment.

FIG. 11 is a side cross-sectional view of a positioning device according to a fourth exemplary embodiment.

### DESCRIPTION OF EMBODIMENT

Exemplary embodiments of the present invention will be described in detail hereinafter on the basis of the drawings. The following description of preferred exemplary embodiments is merely essentially examples, and is not intended to limit the present invention and applications or uses of the present invention.

### First Exemplary Embodiment

(Configuration of positioning device)

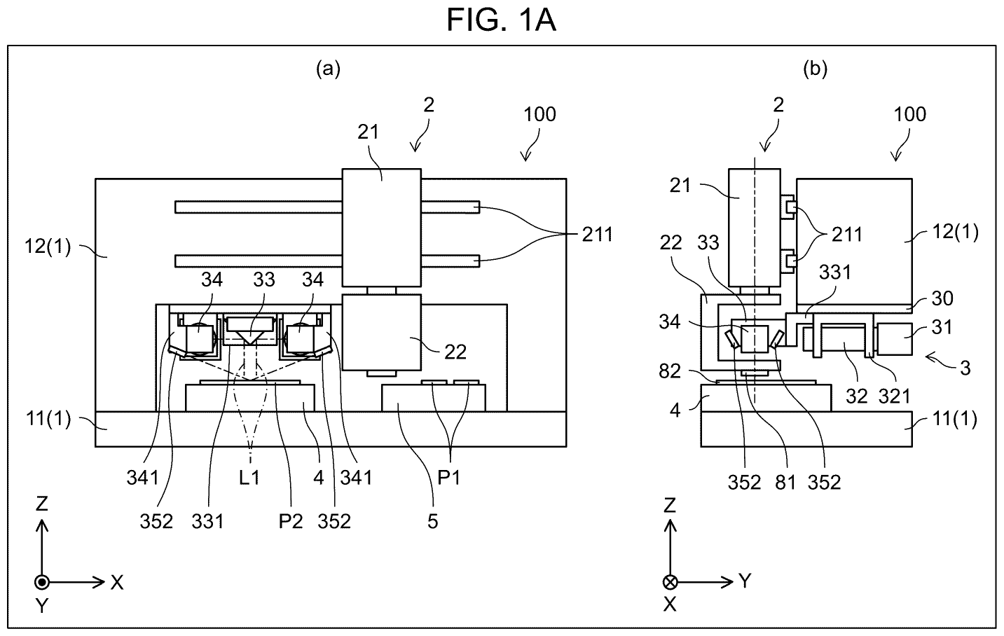

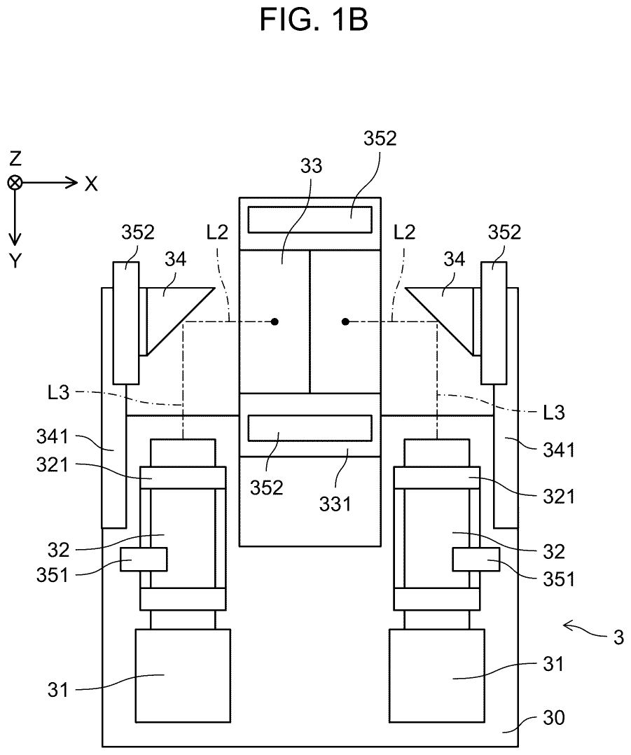

FIGS. 1A and 1B illustrate a positioning device according to a first exemplary embodiment. Specifically, FIG. 1A(a) is a front view of positioning device 100, FIG. 1A(b) is a side cross-sectional view of positioning device 100, and FIG. 1B is a bottom cross-sectional view of positioning device 100. Note that, in the following description, a lateral direction in the drawing in FIG. 1(a) is an X direction (first direction), a depth direction in the drawing (an optical axis direction of camera 31) is a Y direction (third direction), and a vertical direction in the drawing (hereinafter simply referred to as a “vertical direction”) is a Z direction (second direction).

As illustrated in FIG. 1, positioning device 100 according to the first exemplary embodiment includes exterior 1, joining head 2, optical unit 3, joining stage 4, component supplier 5, and processor 6 (not illustrated). For example, processor 6 controls operation of each of the other components and analyzes an image captured by cameras 31 (31a, 31b) as described later.

First components P1 are placed on component supplier 5. Second component P2 is placed on joining stage 4. First components Pl are, for example, an IC, an optical element, a semiconductor package, and the like. Second component P2 is, for example, a wafer, a silicon substrate, a printed board, or the like. Note that, in the following description, first components P1 and second component P2 might be collectively referred to as “workpieces” (also referred to as “workpieces W”.).

Exterior 1 includes base 11 and frame 12 (vibration suppressing member). Base 11 and frame 12 are made of members having high rigidity. Base 11 is formed in a substantially flat plate shape. Joining stage 4 and component supplier 5 are disposed on an upper surface of base 11. Frame 12 is formed in such a way as to cover optical unit 3. Joining head 2, optical unit 3, and base 11 are connected to frame 12. Since frame 12 is made of a member having high rigidity, it is possible to suppress transmission of vibration caused by driving of head driver 21 of joining head 2 described later to optical unit 3. Guide rails 211 extending in the X direction are also formed on frame 12.

Joining head 2 includes head driver 21 (first movement mechanism) and workpiece holder 22.

Head driver 21 is a unit that includes a driver (not illustrated) and that drives joining head 2 itself including workpiece holder 22. Specifically, head driver 21 moves joining head 2 in the X direction along guide rails 211. At least head driver 21 can move workpiece holder 22 from above component supplier 5 to above joining stage 4. In addition, head driver 21 can move workpiece holder 22 in the Y direction and the Z direction. In addition, head driver 21 can rotate workpiece holder 22 about the Z direction. At this time, head driver 21 mainly rotates first component P1 held by workpiece holder 22 in the Z direction, but this is not necessarily the case.

Workpiece holder 22 has a surface for holding first component P1 on a lower surface thereof. In addition, workpiece holder 22 is formed in a substantially U-shape when viewed in the X direction (see FIG. 1A (b)). Accordingly, even when joining head 2 moves along guide rails 211, workpiece holder 22 and optical unit 3 do not interfere with each other. Note that workpiece holder 22 may have any shape as long as it does not interfere with optical unit 3 when joining head 2 moves along guide rails 211. For example, workpiece holder 22 may have a substantially L shape.

Optical unit 3 includes a pair of cameras 31 (first cameras), a pair of lenses 32, one reflection prism 33, and a pair of reflection mirrors 34. Cameras 31 and lenses 32 are held by lens holders 321. Reflection prism 33 is held by prism holder 331. Reflection mirrors 34 are held by mirror holders 341. Lens holders 321, prism holder 331, and mirror holders 341 are attached to position detection unit base 30.

As illustrated in FIG. 1B, reflection mirrors 34 are disposed on optical axes of

cameras 31 and lenses 32. In addition, reflection prism 33 has two reflection surfaces on a lower surface thereof, and the reflection surfaces reflect light incident from below to reflection mirrors 34. With this arrangement, cameras 31 can capture an image of components (for example, first component P1 and the second component P2) disposed below reflection prism 33.

In addition, lens holders 321 are provided with coaxial lights 351 (first light sources) that emit light coaxially with the optical axes of cameras 31 and lenses 32. In addition, mirror holders 341 are provided with oblique lights 352 (second light sources) that emit light from oblique angles with respect to the optical axes of cameras 31 and lenses 32. Coaxial lights 351 and oblique lights 352 are for making an image captured by cameras 31 clear. FIGS. 1A and 1B illustrate merely one of examples of arrangement of coaxial lights 351 and oblique lights 352, and any arrangement may be employed as long as the image captured by cameras 31 can be a clear image. In addition, if the image captured by cameras 31 is clear, coaxial lights 351 and oblique lights 352 may not be provided.

Here, mark M1 (corresponds to a first mark, not illustrated in FIGS. 1A and 1B) used to position a workpiece is attached to an upper surface of each first component P1, and mark M2 (corresponds to a second mark, not illustrated in FIGS. 1A and 1B) used to position a workpiece is attached to an upper surface of second component P2. When a workpiece is positioned, first component P1 and second component P2 are disposed below reflection prism 33, and then cameras 31 capture an image of marks M1, M2. At this time, in order to capture the image of marks M1, M2, it is necessary to form images of light reflected from surfaces of first component P1 and second component P2 in cameras 31. At this time, if depth of field of the optical systems such as cameras 31 is sufficiently large and a type of workpiece has not been changed, light reflected from the surfaces of first component P1 and second component P2 can be imaged (focused) in cameras 31. In consideration of suppressing capital investment, it is desirable that the positioning device can handle various workpieces. In the present exemplary embodiment, therefore, drivers that drive reflection prism 33, the pair of reflection mirrors 34, the pair of cameras 31, and the pair of lenses 32 are provided.

Specifically, a driver (corresponding to a second movement mechanism) configured in prism holder 331 drives reflection prism 33 in the Z direction. Drivers (corresponding to third movement mechanisms) configured in mirror holders 341 drive reflection mirrors 34 in the Y direction. Drivers (corresponding to fourth movement mechanisms) configured in lens holders 321 drive cameras 31 and lenses 32 in the Y direction. By driving these drivers and moving cameras 31, lenses 32, reflection prism 33, and reflection mirrors 34 in such a way as to keep distances of optical axes from cameras 31 to the workpiece constant, light reflected on the surfaces of first component P1 and second component P2 can be imaged (focused) in cameras 31 even when the type of workpiece has been changed or the depth of field of the optical systems is not high.

Note that, in the present exemplary embodiment, when optical axes from lenses 32 to reflection mirrors 34 are optical axes L3, optical axes from reflection mirrors 34 to reflection prism 33 are optical axes L2, and optical axes from reflection prism 33 to the workpiece are optical axes L1, optical axes L1 to L3 are parallel to the Y direction, the X direction, and the Z direction, respectively. This facilitates designing. Optical axes L1 to L3, however, do not necessarily be parallel to the Y direction, the X direction, and the Z direction, respectively.

### Method for Adjusting Visual Field Positions and Focus of Cameras

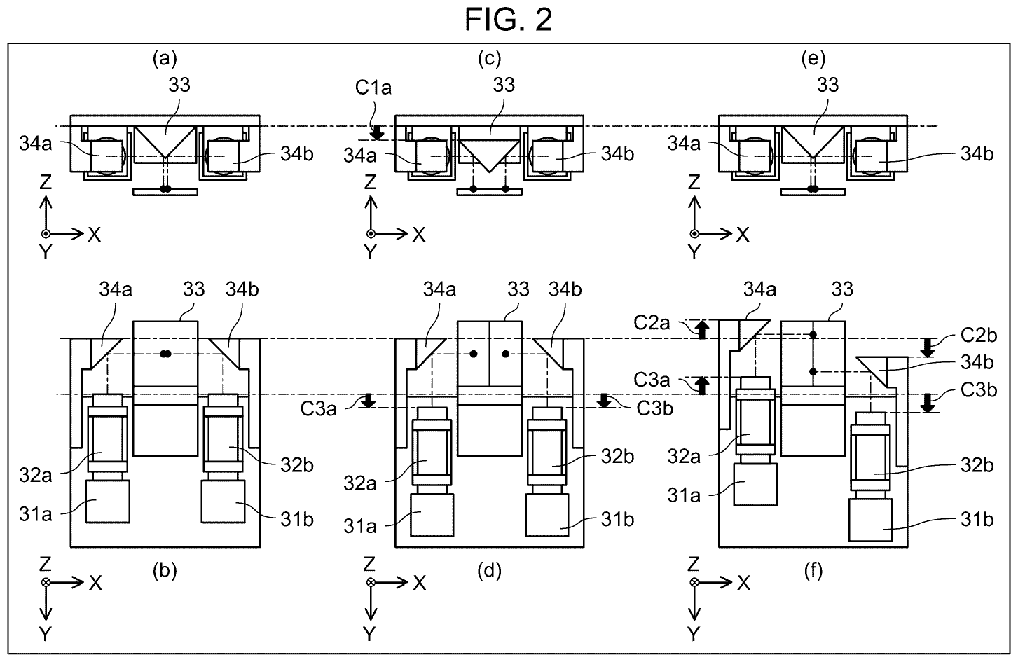

A method for adjusting visual field positions and focus of cameras 31 will be described hereinafter with reference to drawings of FIG. 2. Parts (a), (b) of FIG. 2 are a side view and a bottom view of optical unit 3 when both of the pair of cameras have visual fields thereof at central positions of the workpiece. Parts (c), (b) of FIG. 2 are a side view and a bottom view of optical unit 3 when the pair of cameras has the visual fields thereof at position separated from each other in the X direction. Parts (c), (f) of FIG. 2 are a side view and a bottom view of optical unit 3 when the pair of cameras has the visual fields thereof at positions separated from each other in the Y direction. Note that, in the following description, camera 31, lens 32, and reflection mirror 34 arranged on a left side of each part of FIG. 2 will be described as camera 31a, lens 32a, and reflection mirror 34a, and camera 31, lens 32, and reflection mirror 34 arranged on a right side of each part will be described as camera 31b, lens 32b, and reflection mirror 34b.

Here, assuming that parts (a), (b) of FIG. 2 illustrate reference positions of cameras 31a, 31b, lenses 32a, 32b, reflection prism 33, and reflection mirrors 34a, 34b, the amount of movement of reflection prism 33 in a −Z direction from the reference position is C1a, the amount of movement of reflection mirrors 34a, 34b in a +Y direction from the reference positions are C2a, C2b, respectively, the amount of movement of camera 31a and lens 32a in the +Y direction from the reference positions is C3a, and the amount of movement of camera 31b and lens 32b in the +Y direction from the reference positions is C3b.

In parts (a), (b) of FIG. 2, C1a=C3a=C3b=0. In this state, cameras 31a, 31b are in focus on a position of the workpiece.

In parts (c), (d) of FIG. 2, a position of reflection prism 33 is moved in the −Z direction as compared with parts (a), (b) of FIG. 2. At this time, cameras 31a, 31b are moved in the +Y direction such that C3a=C3b=C1a. In doing so, optical axis distances of the workpiece from cameras 31a, 31b become the same as those in parts (a), (b) of FIG. 2, and an X-direction interval of the visual fields of cameras 31a, 31b can be arbitrarily set while focusing cameras 31a, 31b on the workpiece.

Parts (e), (f) of FIG. 2 are views at a time when the visual field positions have been moved in the Y direction as viewed from parts (a), (b) of FIG. 2. At this time, it is necessary to move C2a and C2b in the Y direction in accordance with the visual field positions. In addition, it is necessary to move C3a, C3b such that a distance of optical axes L1+optical axes L2+optical axes L3 does not change. Since the current state is C1a=0 (reflection prism 33 has not been moved), a state in which the focus is on the workpiece can be set while changing the visual field positions to predetermined Y positions by moving C3a and C3b such that C2a=C3a, C2b=C3b.

Note that although description is omitted, the visual fields of the cameras 31a, 31b can be moved in the X direction and the Y direction by combining the operations of parts (c), (d) and parts (c), (f) of FIG. 2, and the visual field positions can be set at any two points on the workpiece.

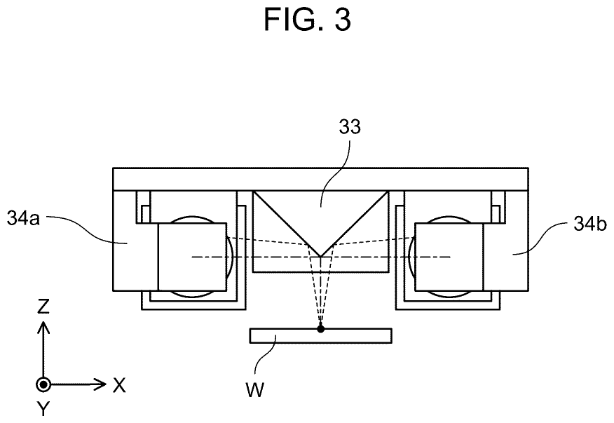

FIG. 3 is a side view illustrating a condensing range of cameras 31a, 31b at a time when the two visual fields of the cameras are about to capture images at substantially the same position according to the first exemplary embodiment (same arrangement as in parts (c), (d) of FIG. 2).

In FIG. 3, the optical axes from cameras 31a, 31b to the workpiece are indicated by dash-dot lines, and center positions of the condensing ranges of cameras 31a, 31b are indicated by broken lines. Angles formed by the broken lines and the dash-dot lines correspond to NAs of lenses 32a, 32b. In this case, camera 31a can obtain an image of workpiece W on a-X direction side from a lower ridge position of reflection prism 33, and camera 31b can obtain an image of workpiece W on a +X direction side from the lower ridge position of reflection prism 33. With this configuration, it is possible to capture an image of almost the entire area up to an intermediate portion between the two visual fields without affecting facility rigidity and the like, and it is easy to handle small workpieces unlike in PTL 1.

### Operation of Positioning Device

As described above, mark M1 used to position the workpiece is attached to the upper surface of each first component P1, and mark M2 used to position the workpiece is attached to the upper surface of second component P2. In the present exemplary embodiment, mounting accuracy is improved by capturing images of marks M1, M2 without changing focus positions of cameras 31. Note that the images of marks M1, M2 may be captured while changing the focus positions of cameras 31, but when an effect of an error due to defocusing is small, an error due to the movement of each component of optical unit 3 does not occur if the images are captured without changing the focus positions of cameras 31, and accordingly the mounting accuracy improves.

In the present exemplary embodiment, a case where two marks M1 are provided on the upper surface of each first component P1 and two marks M2 are provided on the upper surface of second component P2 will be described as an example. In the following description, marks M1 are round-shaped, and marks M2 are quadrangular-shaped. Since a method for calculating a reference point from a plurality of feature points, such as pattern matching, is also possible, however, marks M1, M2 are not limited to actual marks, and may be defined as a position reference point for each of the first component and the second component in each visual field.

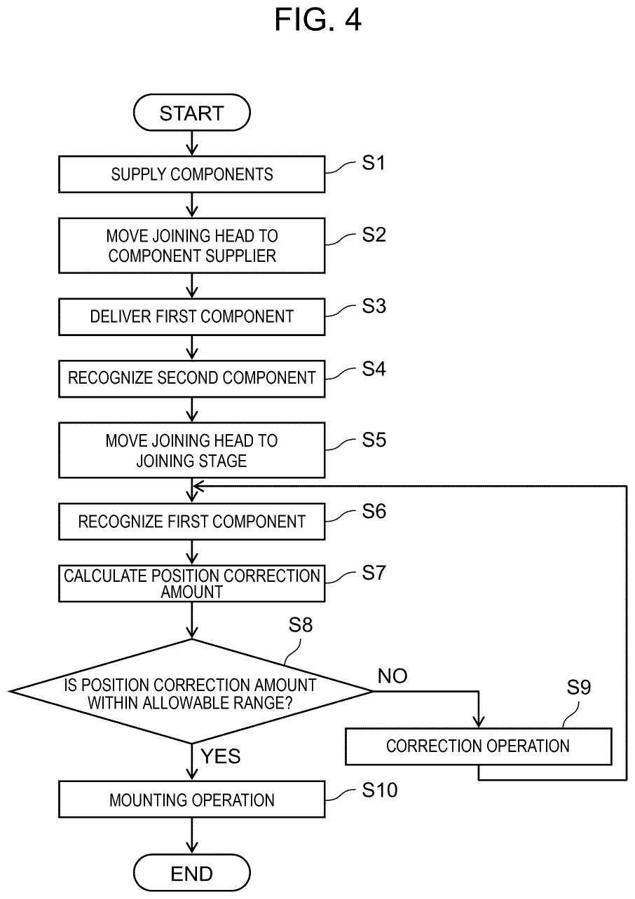

FIG. 4 is a flowchart illustrating operation of the positioning device according to the first exemplary embodiment. Operation of each component of positioning device 100 is controlled by processor 6.

First, first component P1 is supplied (disposed) to component supplier 5, and second component P2 is supplied (disposed) to joining stage 4 (step S1). At this time, first component P1 and second component P2 are disposed on component supplier 5 and joining stage 4, respectively, by a known method. A method for holding first component P1 and second component P2 is sucking and holding, but is not limited thereto. For example, the method for holding first component P1 and second component P2 may be a non-contact method such as a Bernoulli grip when suction, an adhesive sheet such as a gel pack, and contact of a component from a back surface are not preferable.

Joining head 2 is moved above component supplier 5 (+Z direction) (step S2).

First component P1 is delivered from component supplier 5 to joining head 2 (step S3). Specifically, joining head 2 is lowered or component supplier 5 is raised, and first component Pl is held on a lower surface of workpiece holder 22 of joining head 2. First component P1 and component supplier 5 are then separated from each other. Note that step S1 is omitted if direct transfer from another unit (not illustrated) in a facility to joining head 2 is possible. At this time, a shape of the unit and a method for supplying components may be arbitrarily determined.

An operation for recognizing second component P2 is performed (step S4). Specifically, second component P2 placed on joining stage 4 is moved below optical unit 3 (−Z direction), and cameras 31 capture an image of second component P2.

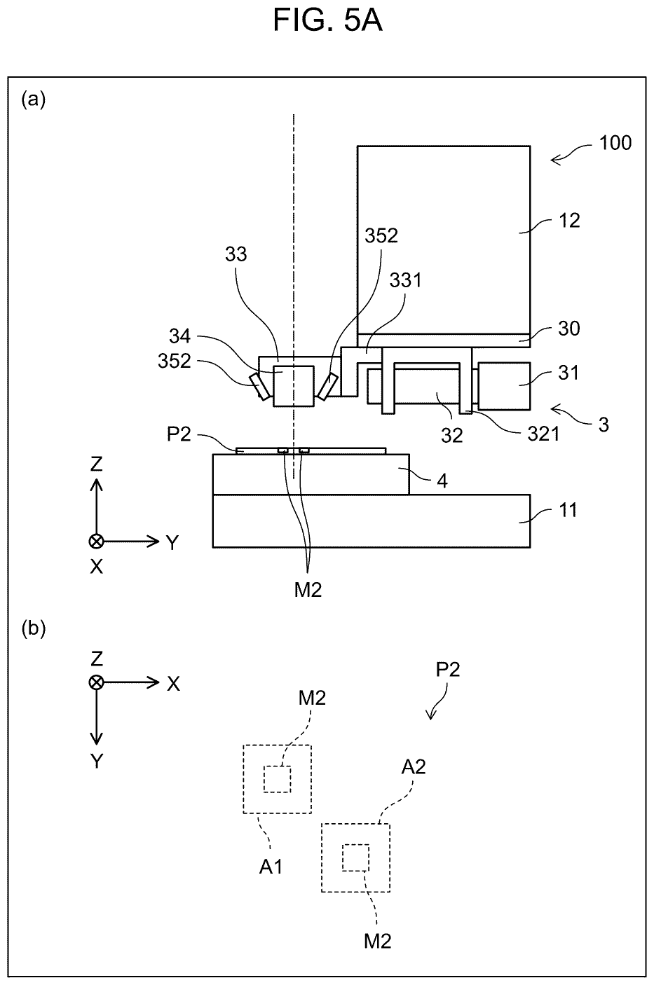

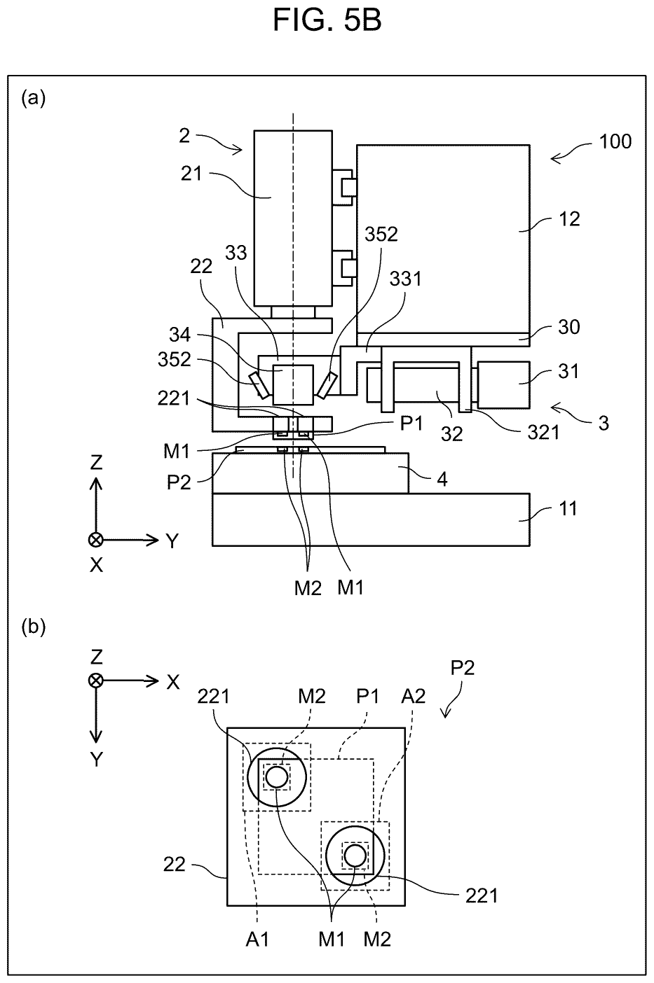

Part (a) of FIG. 5A is a side view illustrating a positional relationship between optical unit 3 and second component P2 in step S4. Part (b) of FIG. 5A is a diagram illustrating an example of the image captured by cameras 31 in step S4. Since optical unit 3 includes two cameras 31, two image capture areas (areas in focus of cameras 31) A1, A2 exist in the captured image (see part (b) of FIG. 5A). In step S4, each component of optical unit 3 is moved such that an image of two marks M2 provided on second component P2 are respectively captured in image capture areas A1, A2. Note that, when size of the workpiece is small, an image of two marks M2 may be captured only in one of image capture areas A1, A2. Note that step S4 may be performed at any timing after step S1 and before step S5.

Joining head 2 is moved above joining stage 4 (+Z direction) (step S5). At this time, positions of first component P1 and second component P2 are brought close to the vicinity of mounting positions (that is, close in the Z direction).

An operation for recognizing first component PI is performed (step S6). Specifically, an image of first component PI held by joining head 2 is captured by cameras 31. Note that although the focusing of cameras 31 is necessary in some cases, an image of marks Ml may be captured without changing focus positions as long as the depth of field allows.

Part (a) of FIG. 5B is a side view illustrating a positional relationship between joining head 2, optical unit 3, first component P1, and second component P2 in step S6. Part (a) of FIG. 5B is a diagram illustrating an example of an image captured by cameras 31 in step S6. When the image of marks M1 is captured in step S6, since first component P1 is held on the lower surface of workpiece holder 22 of joining head 2, it is necessary to prevent workpiece holder 22 from blocking the optical axes from cameras 31 to first component P1. In the first exemplary embodiment, therefore, transmission part 221 is formed in workpiece holder 22. Transmission part 221 is, for example, a hole penetrating workpiece holder 22 in the Z direction or a member that transmits light and that is embedded in the hole, such as glass. Note that, if workpiece holder 22 itself is formed of a member that transmits light, transmission part 221 is unnecessary.

Note that, in step S6, when an extremely small workpiece is recognized, illumination light might interfere with each other if the two cameras simultaneously capture images. When the workpiece is small, for example, since optical unit 3 is arranged as in parts (a), (b) of FIG. 2, part of light emitted from one of coaxial lights 351 passes below prism 33 and enters other camera 31 that does not correspond to the part of light. In this case, two cameras 31 may sequentially capture the images one by one.

Processor 6 calculates a position correction amount from an image of marks M1 (the image of part (b) of FIG. 5A) and an image of marks M2 (the image of part (d) of FIG. 5B) (step S7). The position correction amount is calculated, for example, on the basis of relative positions of marks M1, M2 when the image of marks M1 is compared with the image of marks M2.

Processor 6 determines whether or not the position correction amount is within an allowable range (step S8).

If determining that the position correction amount is not within the allowable range (No in step S8), processor 6 performs a correction operation (step S9). Specifically, processor 6 moves joining head 2 in the X direction and the Y direction and rotates joining head 2 about the Z direction on the basis of the position correction amount. After step S9, the process returns to step S6.

If determining that the position correction amount is within the allowable range (Yes in step S8), processor 6 performs a mounting operation (step S10). Specifically, joining head 2 is lowered (moved in the-Z direction), first component P1 is placed on second component P2, and joining head 2 is raised (moved in the +Z direction).

As described above, the positioning device according to the present exemplary embodiment includes joining head 2 that holds first component P1, joining stage 4 on which second component P2 is placed, optical unit 3 that captures an image of at least one of first component P1 and second component P2, and processor 6 that calculates a position correction amount of first component P1 and second component P2 on the basis of the image captured by optical unit 3. Frame 12 (vibration suppressing member) for suppressing transmission of vibration from joining head 2 to optical unit 3 is disposed between optical unit 3 and joining head 2. With this configuration, frame 12 can suppress vibration due to the movement of joining head 2 from being transmitted to cameras 31 of optical unit 3, and a decrease in positioning accuracy can be suppressed. In PTL 1, on the other hand, since a camera is mounted on a joining head, vibration due to correction movement of the joining head is likely to affect the camera, and there is a concern about a decrease in the positioning accuracy.

In addition, in PTL 1, in order to handle small workpieces, it is necessary to bring image capture areas of substrate cameras close to each other, and in order to realize this, it is necessary to thin a shaft connecting a driver and a component gripper. For this reason, rigidity might decrease to deteriorate mounting accuracy. In addition, because an optically necessary space is larger on a lens side than at a recognition position between the recognition position and a lens, it might be difficult to configure the shaft connecting the gripper and the head depending on size of a workpiece. In the present exemplary embodiment, on the other hand, the movement mechanisms of cameras 31a, 31b, lenses 32a, 32b, reflection prism 33, and reflection mirrors 34a, 34b of optical unit 3 can flexibly handle any pitch between the marks on the workpiece, and can handle any workpiece size without a decrease in facility performance, such as a decrease in facility rigidity.

### Second Exemplary Embodiment

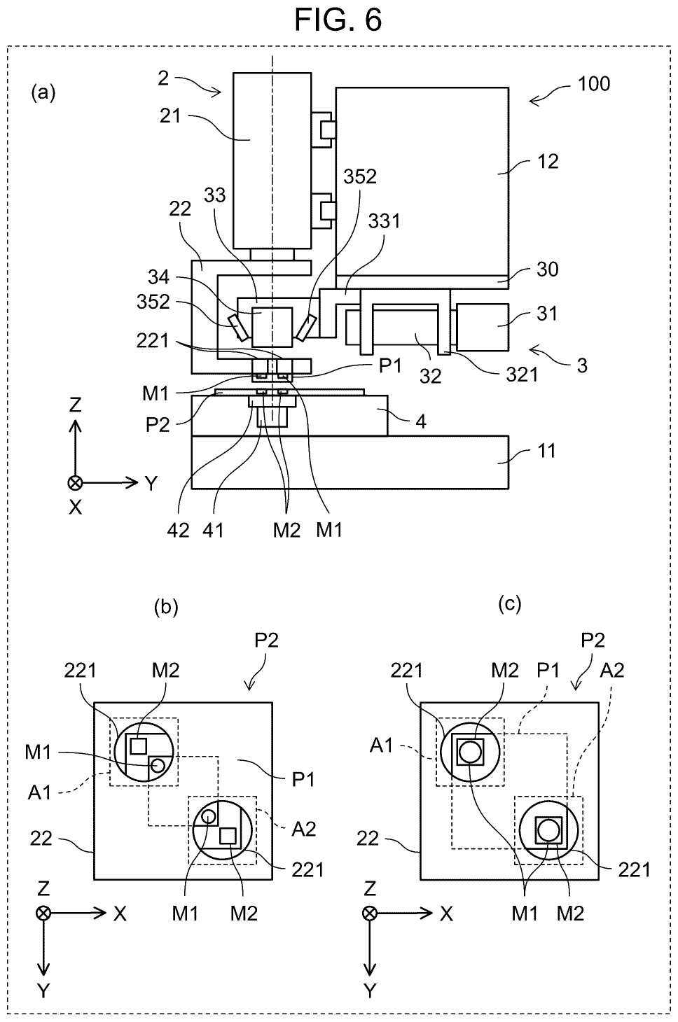

Part (a) of FIG. 6 is a side cross-sectional view of a positioning device according to a second exemplary embodiment. In the second exemplary embodiment, unlike in the first exemplary embodiment, cameras 31 can simultaneously capture an image of marks M1 of first component P1 and an image of marks M2 of second component P2 at once.

Specifically, when first component P1 and second component P2 are viewed in plan view, an image of marks M1 of first component P1 and an image of marks M2 of second component P2 can be simultaneously captured in a case where marks M2 are not on a lower side of first component P1 (see an example of an image captured by cameras 31 in part (b) of FIG. 6), a case where an image of marks M2 can be captured through first component P1 even if marks M2 are on first component P1 (see an example of the image captured by cameras 31 in part (c) of FIG. 6), and the like. Note that, in principle, it is assumed that marks M1 of first component P1 are on an upper side of first component P1, but in the latter case, marks M1 of first component P1 may be on the lower side of first component P1 as long as the image of marks M1 can be captured through first component P1.

For example, when the images of marks M1, M2 are captured through first component P1, light radiated by coaxial lights 351 and oblique lights 352 needs to be light to be transmitted through first component P1. For example, when the workpiece is based on silicon such as a semiconductor, the images of marks M1, M2 can be captured if the light radiated by coaxial lights 351 and oblique lights 352 is infrared light, since the infrared light passes through first component P1 and second component P2. When the light radiated by coaxial lights 351 and oblique lights 352 cannot sufficiently pass through first component P1 and second component P2 and cannot clearly capture images of marks M1, M2, on the other hand, the positioning device illustrated in part (a) of FIG. 6 is used.

As illustrated in part (a) of FIG. 6, stage light 41 (second light source) and transmission part 42 are provided under joining stage 4. Stage light 41 emits illumination light upward, the illumination light being light in a wavelength band that passes through both first component P1 and second component P2. Transmission part 42 is, for example, a member that transmits light, such as glass embedded in joining stage 4. Second component P2 is placed on an upper side of transmission part 42, and the illumination light emitted from stage light 41 is emitted toward the workpieces (first component P1 and second component P2). With this structure, when first component P1 and second component P2 are based on silicon or the like and stage light 41 emits infrared light, for example, the light passes through both first component P1 and second component P2, and cameras 31 can clearly capture the images of the marks.

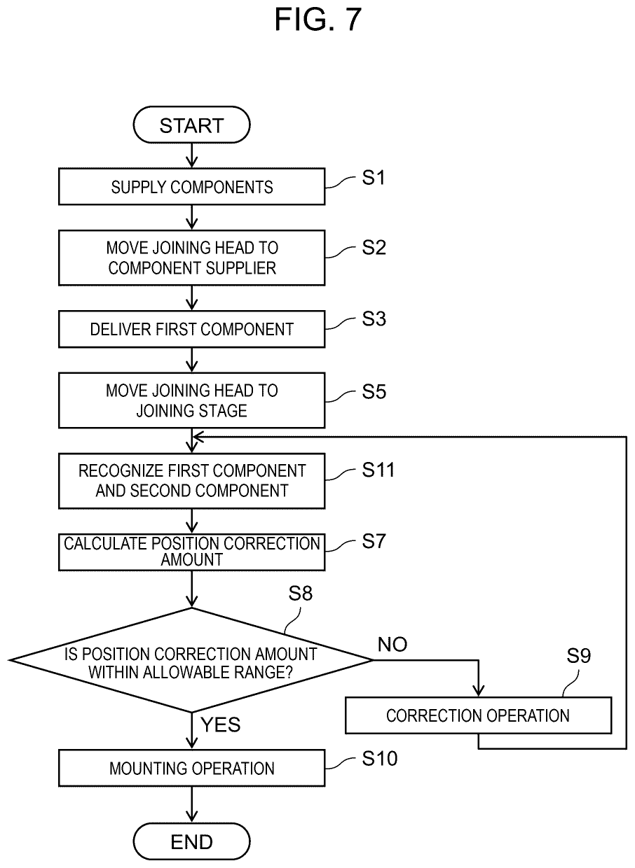

FIG. 7 is a flowchart illustrating operation of the positioning device according to the second exemplary embodiment. In FIG. 7, unlike in FIG. 4, step S4 is omitted, and step S11 is performed instead of step S6.

In step S11, an operation for recognizing first component P1 and second component P2 is performed. Specifically, cameras 31 capture images of first component P1 held by joining head 2 and second component P2 placed on joining stage 4. Note that although the focusing of cameras 31 is necessary in some cases, the images of marks M1, M2 may be captured without changing the focus positions as long as the depth of field allows.

In step S7, processor 6 then calculates the position correction amount from images of marks M1, M2 (images illustrated in part (b), (c) of FIG. 7 or the like).

According to the second exemplary embodiment, it is possible to handle a case where an image of marks M1 of first component PI and an image of marks M2 of second component P2 can be simultaneously captured while producing the same effects in the first exemplary embodiment.

### Third Exemplary Embodiment

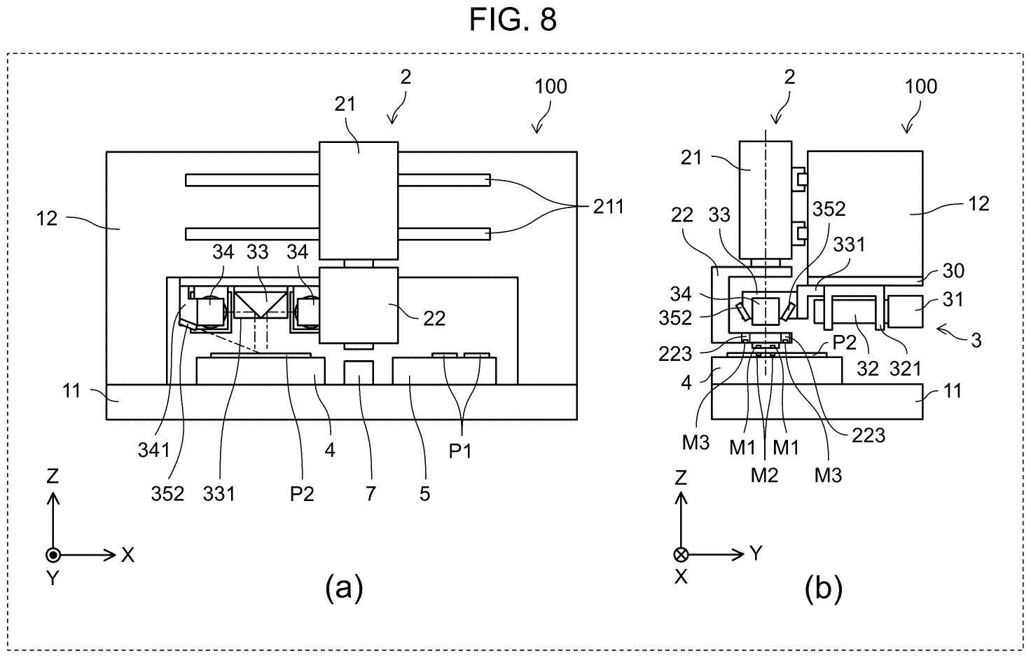

FIG. 8 illustrates a positioning device according to a third exemplary embodiment. Specifically, part (a) of FIG. 8 is a front view of positioning device 100, and part (b) of FIG. 8 is a side-cross sectional view of positioning device 100. The third exemplary embodiment is a mode for handling a case where alignment marks M1 are provided on the lower surface of first component P1.

Specifically, unlike in the first exemplary embodiment, transmission parts 223 and camera 7 (second camera) are provided. In addition, transmission parts 223 are formed in workpiece holder 22 of joining head 2. Transmission parts 223 are, for example, members that transmit light, such as glass, and that are embedded in holes penetrating workpiece holder 22 in the Z direction. Marks M3 (third marks) are provided on lower surfaces of transmission parts 223. Marks M3 are provided at positions not overlapping first component P1 held on the lower surface of workpiece holder 22 and within image capture visual fields of marks M1 when workpiece holder 22 is viewed from a lower side (−Z direction). Note that, in the present exemplary embodiment, the number of cameras 31 and the number of marks M1 and M3 are the same (two).

Camera 7 captures an image of the lower surface of workpiece holder 22 of joining head 2 and the lower surface of first component P1 while joining head 2 moves from above component supplier 5 to above joining stage 4 (from after step S3 to before step S5). In the third exemplary embodiment, marks Ml are provided on the lower surface of first component P1. That is, camera 7 captures an image of both sets of marks M1, M3 while joining head 2 is moving from above component supplier 5 to above joining stage 4. Two cameras 7 may be provided to simultaneously capture images of marks M1, M3, or only one camera 7 may be provided and at least one of the head and the camera may be moved in the horizontal direction to capture an image twice.

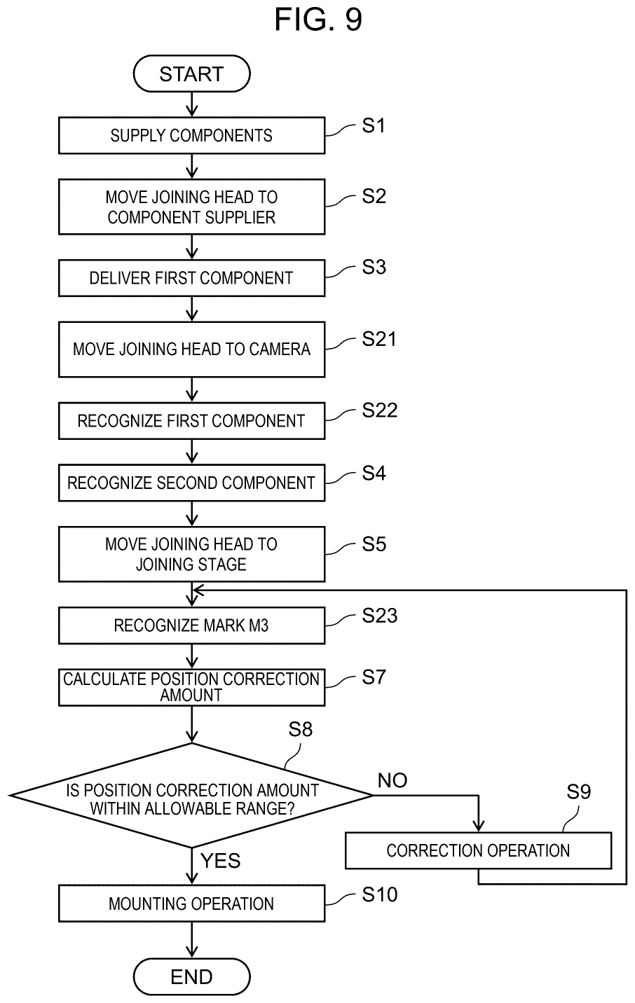

FIG. 9 is a flowchart illustrating operation of the positioning device according to the third exemplary embodiment. In FIG. 9, unlike in FIG. 4, steps S21, S22 are performed after step S3, and step S23 is performed instead of step S6.

In step S21, joining head 2 is moved above camera 7 (+Z direction).

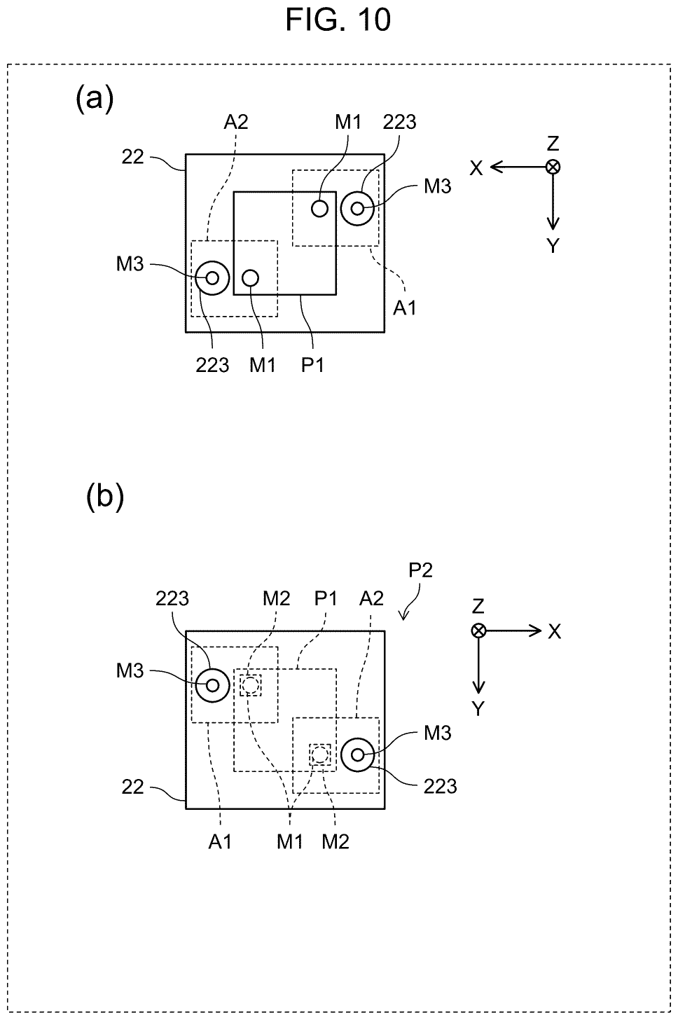

In step S22, an operation for recognizing first component PI and marks M3 is performed. Specifically, camera 7 captures an image of the lower surfaces of first component Pl and workpiece holder 22 held by joining head 2. At this time, the image captured by camera 7 includes marks M1, M3 (see an image captured by camera 7 in part (a) of FIG. 10). Note that, in some cases, an image captured while focusing on each of marks M1 and marks M3 is required, but if the depth of field allows, one image of marks M1, M3 may be captured without changing a focus position. Processor 6 then calculates relative positions of marks M1, M3 from the image.

In step S23, an operation for recognizing marks M3 is performed. Specifically, cameras 31 capture an image of marks M3 (see an image captured by cameras 31 in part (b) of FIG. 10).

In step S7, processor 6 then calculates the position correction amount on the basis of the image captured in step S22 (the image in part (a) of FIG. 10), the image captured in step S4 (see part (b) of FIG. 5), and an image captured in step S23 (an image in part (b) of FIG. 10).

According to the third exemplary embodiment, it is possible to handle a case where marks M1 are provided on the lower surface of first component P1 while producing the same effects as in the first exemplary embodiment.

### Fourth Exemplary Embodiment

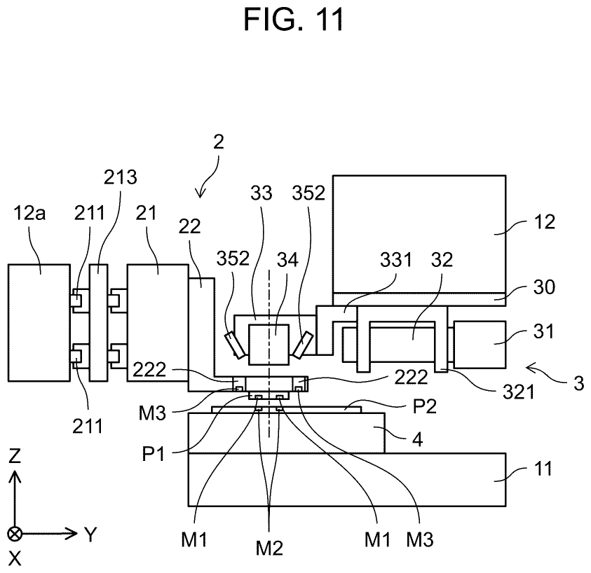

FIG. 11 is a side cross-sectional view of a positioning device according to a fourth exemplary embodiment. In the fourth exemplary embodiment, unlike in the first exemplary embodiment, joining head 2 is attached to frame 12a different from frame 12. In addition, workpiece holder 22 of joining head 2 is formed in a substantially L shape.

Frame 12a is provided with guide rails 211 extending in the X direction, and rotary shaft 213 that moves guide rails 211 and that rotates head driver 21 and workpiece holder 22 about the Z direction.

In the fourth exemplary embodiment, joining head 2 is disposed on frame 12a, and optical unit 3 is disposed on frame 2. That is, optical unit 3 and joining head 2 are disposed apart from each other. As a result, as in the first exemplary embodiment, it is possible to suppress the vibration due to the movement of joining head 2 from being transmitted to cameras 31 of optical unit 3, and it is possible to suppress a decrease in the positioning accuracy. In addition, with the above configuration, a load applied to frame 12 can be distributed.

Note that, in the fourth exemplary embodiment, a form of the workpiece, the structure of joining head 2, and the like can be changed in accordance with the first to third exemplary embodiments.

Although a chip as the first component is mounted on a substrate as the second component in the exemplary embodiments, the first component and the second component are not limited thereto, and the present disclosure may be applied to a case where an imprint mold as a first member is positioned with respect to a substrate coated with a resist as a second member, positioning of points on a joining member as the second member to be processed by a laser as the first member, positioning of measurement points on a measurement member as the second member to be measured by a probe as the first member, and the like.

In addition, in the case of measurement or processing, the second member is not limited to the lower surface, and may be held or disposed on a specific reference surface such as a side surface or an upper surface of the head, instead.

### INDUSTRIAL APPLICABILITY

The positioning device in the present disclosure can be used when electronic components such as electronic components are mounted or during positioning at a time of manufacturing, such as positioning of members disposed on a head and a stage, processing points, and measurement points.

### REFERENCE MARKS IN THE DRAWINGS

100: positioning device
1: exterior
12: frame (vibration suppressing member)
2: joining head
21: head driver (first movement mechanism)
213: rotary shaft
22: workpiece holder (holding surface)
221, 223: transmission part
3: optical unit
31 (31a, 31b): camera (first camera)
32 (32a, 32b): lens
33: reflection prism
34 (34a, 34b): reflection mirror
351: coaxial light (first light)
352: oblique light (first light)
4: joining stage
41: stage light (second light)
5: component supplier
6: processor
7: camera (second camera)
A1, A2: image capture area
M1 to M3: marks (first to third marks)
P1: first component
P2: second component

1. A positioning device that performs positioning when a first component is mounted on a second component, the positioning device comprising:
a joining head that holds the first component;
a joining stage on which the second component is placed;
an optical unit that captures an image of at least one of the first component and the second component; and
a processor that calculates a position correction amount of the first component and the second component based on the image captured by the optical unit, wherein
a vibration suppressing member for suppressing transmission of vibration from the joining head to the joining head is disposed between the optical unit and the joining head, or the optical unit and the joining head are disposed apart from each other,
the optical unit includes:
a first camera for capturing the image;
a lens disposed to correspond to the first camera; and
an optical element that changes an optical axis direction of the first camera, the optical element includes:
a reflection mirror disposed to correspond to the first camera; and
a reflection prism having a reflection surface,
the joining head includes:
a first movement mechanism that is separated from the optical unit and that moves the joining head in a first direction that is a direction parallel to a placement surface of the joining stage; and
a holding surface that holds the first component on a lower surface, and the optical unit includes a second movement mechanism that moves the reflection prism in a second direction that is a vertical direction perpendicular to the first direction.

2. The positioning device according to claim 1, wherein
the first component includes a first mark used when the positioning is performed,
the second component includes a second mark used when the positioning is performed, and
when the positioning is performed,
the first component and the second component are disposed to overlap each other in plan view,
the reflection prism is disposed above the first component, and
the first camera captures images of the first mark and the second mark.

3. The positioning device according to claim 1, wherein
the optical unit includes:
a third movement mechanism that moves the reflection mirror in a third direction perpendicular to the first direction and the second direction; and
a fourth movement mechanism that moves the first camera and the lens in the third direction.

4. The positioning device according to claim 1, further comprising a first light source that radiates light onto at least one of the first component and the second component from an angle coaxial or oblique to an optical axis of the first camera.

5. The positioning device according to claim 1, wherein
the joining head includes a transmission part that transmits visible light or infrared light, and
the first camera captures an image of the first component through the transmission part.

6. The positioning device according to claim 1, wherein
at least one of the first component and the second component is formed of a member that transmits visible light or infrared light, and
the first camera simultaneously captures images of the first component and the second component.

7. The positioning device according to claim 1, wherein the joining stage includes a second light source that radiates visible light or infrared light onto at least one of the first component and the second component through the joining stage.

8. The positioning device according to claim 1, wherein
the joining head includes a third mark whose image is captured from below or above the joining head, and
the positioning device further comprising a second camera that captures an image of the third mark and the first component from below the joining head.

9. A positioning method using the positioning device according to claim 1, the positioning method comprising:
a first step of moving the joining head above a component supplier that supplies the first component;
a second step of holding the first component with the joining head;
a third step of capturing, with the optical unit, an image of the second component placed on the joining stage;
a fourth step of moving the joining head above the joining stage;
a fifth step of capturing, with the optical unit, an image of the first component held by the joining head; and
a sixth step of calculating, with the processor, the position correction amount based on the images captured by the optical unit.

10. The positioning method according to claim 9, further comprising
a seventh step of determining, with the processor, whether or not the position correction amount is within an allowable range, wherein
in the seventh step, when determining that the position correction amount is not within the allowable range, the processor corrects relative positions of the first component and the second component, and when determining that the position correction amount is within the allowable range, the processor joins the first component and the second component to each other.

11. The positioning method according to claim 9, wherein
the first component includes a first mark used when the positioning is performed, and
in the fifth step, the optical unit captures an image of the first mark while passing through or avoiding the joining head.

12. The positioning method according to claim 11, wherein
the second component includes a second mark used when the positioning is performed,
the third step and the fifth step are performed after the fourth step, or a ninth step of simultaneously capturing an image of the second component placed on the joining stage and an image of the first component held by the joining head is performed, and
in the third or ninth step, the optical unit captures an image of the second mark while passing through or avoiding the joining head.

13. The component positioning method according to claim 9, wherein
the first component includes a first mark used when the positioning is performed,
the joining head includes a third mark whose image is captured from below or above the joining head,
the positioning device further includes a second camera that captures an image of the third mark and the first component from a lower side of the joining head, and
the positioning method further comprising an eighth step of capturing an image of the first mark and the third mark with the second camera after the second step.

14. The positioning method according to claim 13, wherein the second camera captures the image of the first mark and the third mark without moving horizontal positions of the second camera and the joining head.

15. A positioning device that positions a first member with respect to a second member, the positioning device comprising:
a head that holds the first member;
a stage on which the second member is placed;
an optical unit that captures an image of at least one of the first member and the second member; and
a processor that calculates a position correction amount of the first member and the second member based on the image captured by the optical unit, wherein
a vibration suppressing member for suppressing transmission of vibration from the head to the head is disposed between the optical unit and the head, or the optical unit and the head are disposed apart from each other,
the optical unit includes:
a first camera for capturing the image;
a lens disposed to correspond to the first camera; and
an optical element that changes an optical axis direction of the first camera, the optical element includes:
a reflection mirror disposed to correspond to the first camera; and
a reflection prism having a reflection surface, the head includes:
a first movement mechanism that is separated from the optical unit and that moves the head in a first direction that is a direction parallel to a placement surface of the stage; and
a holding surface that holds the first member on a reference surface, and
the optical unit includes a second movement mechanism that moves the reflection prism in a second direction that is a vertical direction perpendicular to the first direction.
